(19) United States
(12) Patent Application Publication
(10) Pub. No.: US 2011/0285245 A1
(43) Pub. Date: Nov. 24, 2011

(54) ANODIC WAFER BONDING METHOD, METHOD OF MANUFACTURING PACKAGES, METHOD OF MANUFACTURING PIEZOELECTRIC VIBRATORS, OSCILLATOR, ELECTRONIC APPARATUS, AND RADIO CLOCK

(76) Inventor: Kiyoshi Aratake, Chiba-shi (JP)

(21) Appl. No.: 13/196,396

(22) Filed: Aug. 2, 2011

Related U.S. Application Data
(63) Continuation of application No. PCT/JP2009/053330, filed on Feb. 25, 2009.

(51) Int. Cl. H01L 41/00; B32B 38/10; B32B 37/06

(52) U.S. Cl. 310/319; 156/273.9; 156/250

(57) ABSTRACT

An anodic wafer bonding method according to the present invention is an anodic wafer bonding method for bonding a first substrate formed of an insulating material or a dielectric material and a second substrate which can be anodically bonded by applying a voltage to a bonding film formed of a conductive material formed between the substrates in a state in which the first substrate and the second substrate are laminated, in which the voltage is applied to the bonding film from a plurality of points at the time of anodic wafer bonding.

### RELATED APPLICATIONS

This application is a continuation of PCT/JP2009/053330 filed on Feb. 25, 2009. The entire content of this application is incorporated herein by reference.

### BACKGROUND OF THE INVENTION

1. Field of the Invention

The present invention relates to an anodic wafer bonding method for anodically bonding by applying a voltage to a bonding film formed between a pair of members, a method of manufacturing packages using anodic wafer bonding, a method of manufacturing piezoelectric vibrators, an oscillator, an electronic apparatus, and a radio clock.

2. Description of the Related Art

In recent years, a piezoelectric vibrator using crystal or the like as a time instance source, a timing source of control signals or the like, a reference signal source, and so on in mobile phone sets or portable digital assistant terminal is used. Various types of such piezoelectric vibrators are known, and a piezoelectric vibrator of surface mount device type is known as one of these piezoelectric vibrators. As the piezoelectric vibrator of this type, a three-layer structure type in which a base substrate and a lid substrate are bonded to piezoelectric substrate formed with a piezoelectric vibration reed thereon so as to interpose the same therebetween from above and below is generally known. In this case, the piezoelectric vibrator is stored in a cavity (sealed chamber) formed between the base substrate and the lid substrate. Also, in recent years, there is also developed a two-layer structure type instead of the three-layer structure type described above.

The piezoelectric vibrator of this type has a packaged two-layer structure having the base substrate and the lid substrate bonded directly to each other, and the piezoelectric vibration reed is stored in the cavity formed between the both substrates. The piezoelectric vibrator of the packaged two-layer structure type is superior in reduction in thickness is achieved, for example, in comparison with those having the three-layer structure, and is preferably used. As one of the piezoelectric vibrators of the packaged two-layer structure type as described above, a piezoelectric vibrator in which a piezoelectric vibration reed and an external electrode formed on a base substrate is brought into continuity using a conductive member formed so as to penetrate through the base substrate is known (for example, Patent Document 1 and Patent Document 2). As a method of directly bonding the base substrate and the lid substrate, an anodic wafer bonding method for bonding both the substrates by forming a bonding film between both the substrates and applying a voltage to the bonding film is proposed.
Patent Document 1: JP-A-2001-267190
Patent Document 2: JP-A-2007-328941

Incidentally, when manufacturing a package having a base substrate and a lid substrate in the related art, a method of forming a bonding film between a pair of wafers including a base substrate wafer formed with a plurality of the base substrates and a lid substrate wafer formed also with a plurality of the lid substrates, anodically bonding the wafers entirely, and then individualizing the same into packages is generally employed. Also, as shown in FIG. 18 and FIG. 19, when anodically bonding is performed with respect to a pair of wafers 240, 250, anodic wafer bonding is achieved by forming a notch 253 in the peripheral edge portion of one wafer 250 at one position, connecting an electrode 263 for applying a voltage to a bonding film 235 exposed from the notch 253, installing an electrode panel 261 on an upper surface of the wafer 250, and passing electric current through the bonding film 235 by applying a voltage between the electrode panel 261 and the electrode 263.

In contrast, in recent years, since enlarging the diameter of the wafers is in progress, if an attempt is made to bond the entire wafers having enlarged surface area by the anodic wafer bonding, it is necessary to pass a heavy current. However, when the heavy current is passed to one point, the bonding film may be damaged due to occurrence of temperature rise, discoloration, burning or the like. Therefore, there is a problem that if the diameter of the wafer is enlarged, the anodic wafer bonding of the pair of wafers is not achieved.

In view of such circumstances as described above, it is an object of the present invention to provide an anodic wafer bonding method which can be anodically bonded with high reliability irrespective of the size of bonded objects, a method of manufacturing packages, a method of manufacturing piezoelectric vibrators, an oscillator, an electronic apparatus, and a radio clock.

### SUMMARY OF THE INVENTION

In order to solve the problems as described above, the present invention provides following means.

An anodic wafer bonding method according to the present invention is an anodic wafer bonding method for bonding a first substrate formed of an insulating material or a dielectric material and a second substrate which can be anodically bonded by applying a voltage to a bonding film formed of a conductive material formed between the substrates in a state in which the first substrate and the second substrate are laminated, characterized in that the voltage is applied to the bonding film from a plurality of points at the time of anodic wafer bonding.

In the anodic wafer bonding method according to the present invention, a current value flowing per point can be reduced by applying the voltage to the bonding film from a plurality of points. Therefore, the bonding film 35 can be prevented from being damaged by a heavy current, so that the anodic wafer bonding between the first substrate and the second substrate is ensured. Also, by setting the number of points where the voltage is applied according to the size of the substrates to be anodically bonded, the anodic wafer bonding with high reliability is achieved irrespective of the size of the substrates. In addition, since the bonding film can be prevented from being damaged, a yield ratio can be improved.

Also, the anodic wafer bonding method according to the present invention is characterized in that the voltage is applied to a center portion of the first substrate or the second substrate from a plurality of circumferentially equidistant points.

In the anodic wafer bonding method according to the present invention, since the voltage is applied to the center portion of the first substrate or the second substrate in a well balanced manner, the current value flowing in the bonding film can be uniformized. Therefore, the anodic wafer bonding can be performed in substantially uniform conditions for the entire substrates, and then the quality of a plurality of the individual pieces obtained by cutting the substrates into pieces can be uniformized.

The anodic wafer bonding method according to the present invention is characterized in that a through hole is formed at the center portion on any one of the first substrate and the second substrate, and the voltage is applied to the bonding film formed at the position corresponding to the center portion.

In the anodic wafer bonding method according to the present invention, since the voltage is applied also to the center portion of the substrate, the current value flowing in the bonding film can be further uniformized. Therefore, the anodic wafer bonding can be performed in substantially uniform conditions for the entire substrates, and then the quality of a plurality of the individual pieces obtained by cutting the substrates into pieces can be further uniformized.

The anodic wafer bonding method according to the present invention is characterized in that the first substrate and the second substrate are glass substrates.

In the anodic wafer bonding method according to the present invention, in order to anodically bond the glass substrates with respect to each other, it is necessary to apply a voltage directly to the bonding film. However, by applying the voltage to the bonding film from a plurality of points, the current value flowing per point can be lowered. Therefore, the bonding film can be prevented from being damaged by a heavy current, so that the anodic wafer bonding between the first substrate and the second substrate formed of glass substrates is ensured.

A method of manufacturing packages according to the present invention includes forming depressed-shaped cavities on at least one of the first substrate or the second substrate; and bonding and integrating the first substrate and the second substrate by the anodic wafer bonding method according to any one of those described above, and then dividing the integrated substrates into individual pieces and forming a plurality of packages.

In the method of manufacturing the packages according to the present invention, the current value flowing per point can be lowered by applying the voltage to the bonding film from a plurality of points. Therefore, the bonding film can be prevented from being damaged by a heavy current, so that the packages in which the anodic wafer bonding between the first substrate and the second substrate is ensured can be manufactured. In addition, by setting the number of points where the voltage is applied according to the size of the substrates to be anodically bonded, the packages which are anodically bonded with high reliability irrespective of the size of the substrates can be manufactured. In addition, since the bonding film can be prevented from being damaged, the yield ratio can be improved.

A method of manufacturing piezoelectric vibrators according to the present invention includes: forming depressed cavities on at least one of the first substrate and the second substrate, and then mounting piezoelectric vibration reeds in the cavities; and bonding and integrating the first substrate and the second substrate by the anodic wafer bonding method according to any of those described above, and then dividing the integrated substrates into individual pieces and forming a plurality of packages.

In the method of manufacturing the piezoelectric vibrators according to the present invention, the current value flowing per point can be lowered by applying the voltage to the bonding film from a plurality of points. Therefore, the bonding film can be prevented from being damaged by a heavy current, so that piezoelectric vibrators in which the anodic wafer bonding between the first substrate and the second substrate is ensured can be manufactured. In addition, by setting the number of points where the voltage is applied according to the size of the substrates to be anodically bonded, the piezoelectric vibrators which are anodically bonded with high reliability irrespective of the size of the substrates can be manufactured. In addition, since the bonding film can be prevented from being damaged, the yield ratio can be improved.

An oscillator according to the present invention is characterized in that the piezoelectric vibrator manufactured by the manufacturing method described above is electrically connected to an integrated circuit as an oscillation element.

An electronic apparatus is characterized in that the piezoelectric vibrator manufactured by the manufacturing method described above is electrically connected to a clocking unit.

A radio clock is characterized in that the piezoelectric vibrator manufactured by the manufacturing method described above is electrically connected to a filter unit.

In the oscillator, the electronic apparatus, and the radio clock according to the present invention, since the anodic wafer bonding between the base substrate and the lid substrate is ensured, and the high quality piezoelectric vibrator improved in yield ratio is provided, the reliability of the operation can be enhanced in the same manner and hence the improvement in quality is achieved.

In the anodic wafer bonding method according to the present invention, the current value flowing per point can be reduced by applying the voltage to the bonding film from a plurality of points. Therefore, the bonding film can be prevented from being damaged by a heavy current, so that the anodic wafer bonding between the first substrate and the second substrate is ensured. Also, by setting the number of points where the voltage is applied according to the size of the substrates to be anodically bonded, anodic wafer bonding with high reliability is achieved irrespective of the size of the substrates. In addition, since the bonding film can be prevented from being damaged, the yield ratio can be improved.

### BRIEF DESCRIPTION OF THE DRAWINGS

FIG. 1 is an appearance perspective view showing an embodiment of a piezoelectric vibrator according to the present invention.

FIG. 2 is a drawing showing an internal configuration of the piezoelectric vibrator shown in FIG. 1 and is a drawing of a piezoelectric vibration reed viewed from above in a state in which a lid substrate is removed.

FIG. 3 is a cross-sectional view of a piezoelectric vibrator according to the embodiment of the present invention (a cross-sectional view taken along the line A-A in FIG. 2).

FIG. 4 is an exploded perspective view of the piezoelectric vibrator shown in FIG. 1.

FIG. 5 is a top view of the piezoelectric vibration reed which constitutes the piezoelectric vibrator shown in FIG. 1.

FIG. 6 is a bottom view of the piezoelectric vibration reed shown in FIG. 5.

FIG. 7 is a cross-sectional view taken along the line B-B in FIG. 5.

FIG. 8 is a flowchart showing a flow when the piezoelectric vibrator shown in FIG. 1 is manufactured.

FIG. 9 is a drawing showing a step taken when manufacturing the piezoelectric vibrator according to the flowchart shown in FIG. 8, showing a state in which a plurality of depressed portions, notches, and through holes are formed on a lid substrate wafer as an original of the lid substrate.

FIG. 10 is a drawing showing the step taken when manufacturing the piezoelectric vibrator according to the flowchart shown in FIG. 8, and is a drawing showing a state in which a bonding film and a drawing electrode are patterned on an upper surface of a base substrate wafer later.

FIG. 11 is a partially enlarged perspective view of the base substrate wafer in the state shown in FIG. 10.

FIG. 12 is a drawing showing the step taken when manufacturing the piezoelectric vibrator according to the flowchart shown in FIG. 8, and is a drawing showing a state in which anodic wafer bonding is performed on a pair of wafers.

FIG. 13 is a cross-sectional view taken along the line C-C in FIG. 12.

FIG. 14 is a drawing showing a step taken when manufacturing the piezoelectric vibrator according to the flowchart shown in FIG. 8, and is an exploded perspective view of a wafer member the piezoelectric vibrator wafer member which is formed by anodically bonding the base substrate and the lid substrate in a state in which the piezoelectric vibration reeds are stored in the cavities.

FIG. 15 is a configuration drawing showing an embodiment of an oscillator according to the present invention.

FIG. 16 is a configuration drawing showing an embodiment of an electronic apparatus according to the present invention.

FIG. 17 is a configuration drawing showing an embodiment of a radio clock according to the present invention.

FIG. 18 is a drawing showing a method of anodic wafer bonding according to a method of manufacturing piezoelectric vibrators in the related art.

FIG. 19 is a cross-sectional view taken along the line D-D in FIG. 18.

### DETAILED DESCRIPTION OF THE PREFERRED EMBODIMENTS

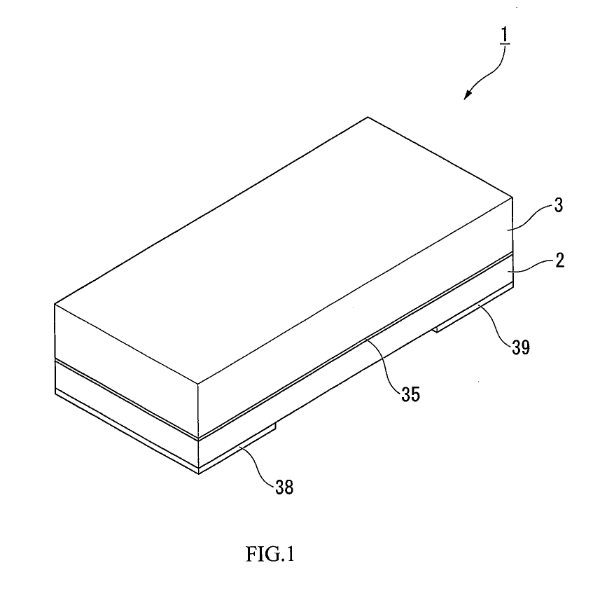

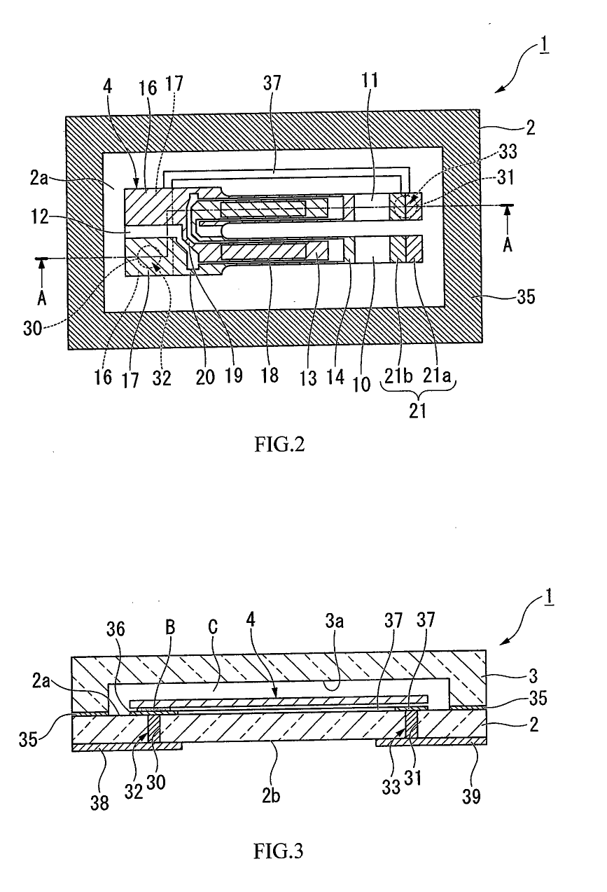

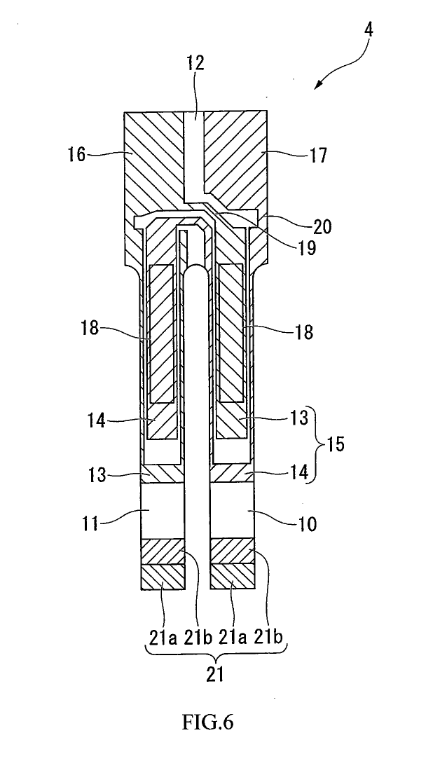

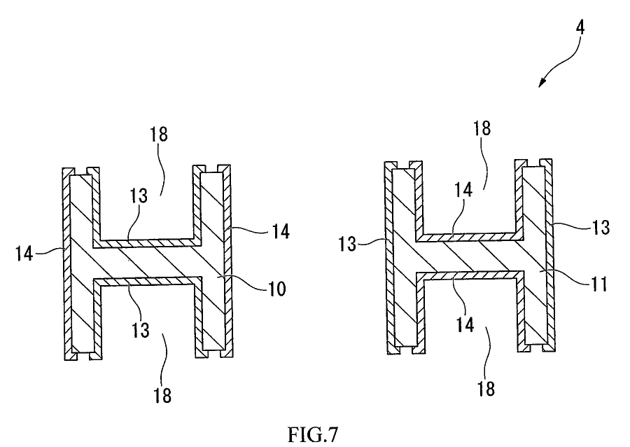

Referring now to FIG. 1 to FIG. 17, an embodiment according to the present invention will be described. In this embodiment, a piezoelectric vibrator in which a base substrate and a lid substrate are laminated, and a piezoelectric vibration reed is mounted in a cavity formed between the substrates, and a method of manufacturing the same will be described.

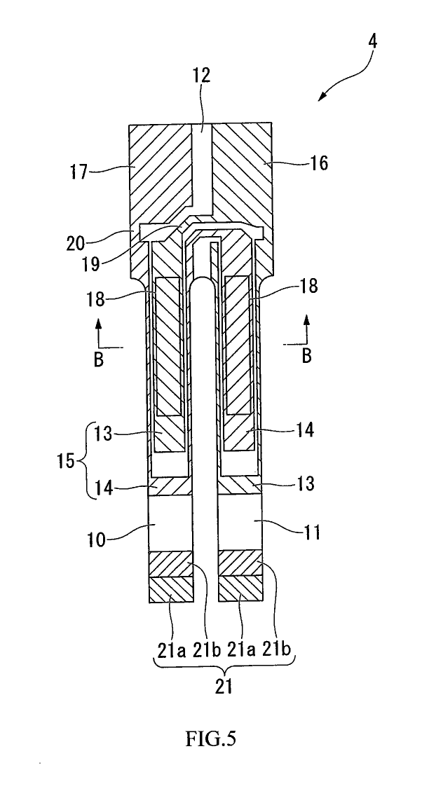

As shown in FIG. 1 to FIG. 4, a piezoelectric vibrator 1 in this embodiment is a piezoelectric vibrator of a surface mount type, which is formed into a box shape with a base substrate 2 and a lid substrate 3 laminated into two layers, and including a piezoelectric vibration reed 4 stored in a cavity C in the interior thereof. In FIG. 4, for the sake of easy understanding of the drawing, illustration of an excitation electrode 15 of the piezoelectric vibration reed 4, drawn electrodes 19, 20, mount electrodes 16, 17, and a weight metal film 21, described later, is omitted.

As shown in FIG. 5 to FIG. 7, the piezoelectric vibration reed 4 is a vibration reed having a tuning fork shape formed of piezoelectric material such as crystal, lithium tantalite, or lithium niobate and is configured to vibrate when a predetermined voltage is applied thereto.

The piezoelectric vibration reed 4 includes a pair of vibrating arm portions 10, 11 arranged in parallel, a base member 12 configured to integrally fix proximal end sides of the pair of vibrating arm portions 10, 11, the excitation electrodes 15 each including a first excitation electrode 13 and a second excitation electrode 14 formed on outer surfaces of the pair of vibrating arm portions 10, 11 for vibrating the pair of vibrating arm portions 10, 11, and the mount electrodes 16, 17 electrically connected to the first excitation electrodes 13 and the second excitation electrodes 14.

The piezoelectric vibration reed 4 in this embodiment also includes groove portions 18 formed respectively on both main surfaces of the pair of vibrating arm portions 10, 11 along a longitudinal direction of the vibrating arm portions 10, 11. The groove portion 18 is formed from the proximal end sides of the vibrating arm portions 10, 11 to substantially midsections thereof.

The excitation electrodes 15 each including the first excitation electrode 13 and the second excitation electrode 14 are electrodes which cause the pair of vibrating arm portions 10, 11 to vibrate in the direction toward and apart from each other at a predetermined resonance frequency and are formed by being patterned on the outer surfaces of the pair of vibrating arm portions 10, 11 in a state of being electrically disconnected, respectively. More specifically, the first excitation electrodes 13 are mainly formed on the groove portions 18 of the one vibrating arm portion 10 and on both side surfaces of the other vibrating arm portion 11, and the second excitation electrodes 14 are mainly formed on both side surfaces of the one vibrating arm portion 10 and the groove portions 18 of the other vibrating arm portion 11.

Also, the first excitation electrodes 13 and the second excitation electrodes 14 are electrically connected to the mount electrodes 16, 17 via the drawn electrodes 19, 20 respectively on both main surfaces of the base member 12. Then, the piezoelectric vibration reed 4 is configured to be applied with a voltage via the mount electrodes 16, 17.

The excitation electrodes 15, the mount electrodes 16, 17, and the drawn electrodes 19, 20 described above are formed by coating conductive films such as chrome (Cr), nickel (Ni), Aluminum (Al) or Titan (Ti).

Distal ends of the pair of vibrating arm portions 10, 11 are each coated with the weight metal film 21 for performing adjustment (frequency adjustment) the vibrating state of themselves to vibrate within a range of a predetermined frequency. The weight metal film 21 is divided into a coarse adjustment film 21a used when adjusting the frequency coarsely and a fine control film 21b used when adjusting the same finely. By performing the frequency adjustment using the coarse control film 21a and the fine control film 21b, the frequencies of the pair of vibrating arm portions 10, 11 can be adjusted to fall within a range of the nominal frequency of the device.

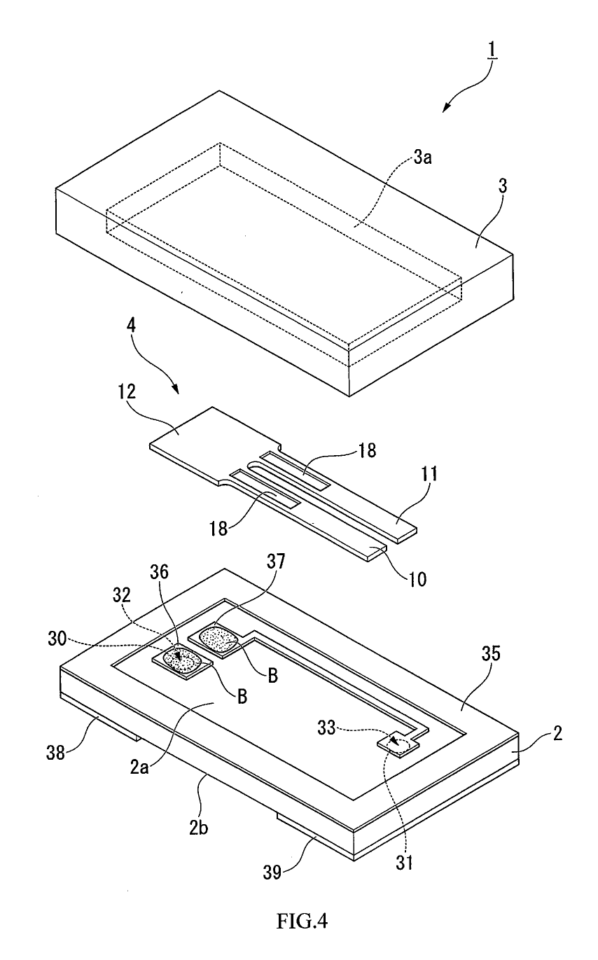

The piezoelectric vibration reed 4 configured in this manner is bonded via the bumps to an upper surface 2a of the base substrate 2 while utilizing a bump B such as gold, as shown in FIG. 3 and FIG. 4. More specifically, the pair of mount electrodes 16, 17 are bonded onto the two bumps B formed on drawing electrodes 36, 37, described later, patterned on the upper surface 2a of the base substrate 2 via the bumps in a state being in contact with each other, respectively. Accordingly, the piezoelectric vibration reed 4 is supported in a state of being lifted from the upper surface 2a of the base substrate 2, and a state in which the mount electrodes 16, 17 and the drawing electrodes 36, 37 are electrically connected respectively is achieved.

The above-described lid substrate 3 is a substrate which is formed of glass material, for example, soda-lime glass, and can be anodically bonded, and is formed into substantially a panel shape as shown in FIG. 1, FIG. 3, and FIG. 4. Then, a rectangular shaped depressed portion 3a for storing the piezoelectric vibration reed 4 is formed on the side of the bonding surface where the base substrate 2 is bonded.

The depressed portion 3a is a depressed portion for cavity which defines the cavity C for storing the piezoelectric vibration reed 4 when the both substrates 2, 3 are placed on top of another. Then, the lid substrate 3 is bonded to the base substrate 2 by anodic wafer bonding in a state in which the depressed portion 3a is opposed to the base substrate 2.

The base substrate 2 described above is a substrate formed of glass material, for example, soda-lime glass, and is formed into substantially a plate shape having a size which can be overlaid on the lid substrate 3 as shown in FIG. 1 to FIG. 4.

The base substrate 2 is formed with a pair of through holes (perforations) 30, 31 penetrating through the base substrate 2. In this case, the pair of through holes 30, 31 are formed so as to be included in the interior of the cavity C. More specifically, the through holes 30, 31 in this embodiment are formed in such a manner that the through hole 30 on one side is formed at a position corresponding to the base member 12 side of the mounted piezoelectric vibration reed 4, and the through hole 31 on the other side is formed at a position corresponding to the distal end sides of the vibrating arm portions 10, 11. In this embodiment, the through holes 30, 31 penetrating straight through the base substrate 2 from a lower surface 2b of the base substrate 2 toward the upper surface 2a are formed. The shapes of the through holes 30, 31 are not limited to the case described above, and may be through holes tapered in cross section gradually reduced in diameter. In any cases, it may be of any shape as long as it penetrates through the base substrate 2.

Then, the pair of through holes 30, 31 are formed with a pair of through electrodes 32, 33 formed so as to clog up the through holes 30, 31. These through electrodes 32, 33 are formed of silver paste fixed integrally to the through holes 30, 31 by baking as shown in FIG. 3, and have a role to maintain the hermeticity in the cavity C by completely closing the through holes 30, 31, and bring external electrodes 38, 39, described later into continuity with the drawing electrodes 36, 37.

On the side of the upper surface 2a of the base substrate 2 (the side of the bonding surface where the lid substrate 3 is bonded), as shown in FIG. 1 to FIG. 4, a bonding film 35 for anodic wafer bonding and a pair of the drawing electrodes 36, 37 are patterned by conductive material such as aluminum. Among them, the bonding film 35 is formed along a peripheral edge of the base substrate 2 so as to surround the periphery of the depressed portion 3a formed on the lid substrate 3.

Also, the pair of drawing electrodes 36, 37 are patterned so as to electrically connect the through electrode 32 which is one of the pair of through electrodes 32, 33 and one of the mount electrodes 16 of the piezoelectric vibration reed 4, and electrically connect the through electrode 33 which is the other one of those and the other mount electrode 17 of the piezoelectric vibration reed 4.

More specifically, the one drawing electrode 36 is formed right above the one through electrode 32 so as to be positioned right below the base member 12 of the piezoelectric vibration reed 4. In contrast, the other drawing electrode 37 is formed so as to be drawn from a position adjacent to the one drawing electrode 36 along the vibrating arm portions 10, 11 to the distal end sides of the vibrating arm portions 10, 11, and then is positioned right above the other through electrode 33.

Then, the bumps B are formed respectively on the pair of drawing electrodes 36, 37, and the piezoelectric vibration reed 4 is mounted using the bumps B. Accordingly, the one mount electrodes 16 of the piezoelectric vibration reed 4 is configured to be brought into continuity with the one through electrode 32 via the one drawing electrode 36, and the other mount electrode 17 is configured to be brought into continuity with the other through electrode 33 via the other drawing electrode 37.

As shown in FIG. 1, FIG. 3, and FIG. 4, the external electrodes 38, 39 which are electrically connected to the pair of through electrodes 32, 33 respectively are formed on the lower surface 2b of the base substrate 2. In other words, the one external electrode 38 is electrically connected to the first excitation electrode 13 of the piezoelectric vibration reed 4 via the one through electrode 32 and the one drawing electrode 36. Also, the other external electrode 39 is electrically connected to the second excitation electrode 14 of the piezoelectric vibration reed 4 via the other through electrode 33 and the other drawing electrode 37.

When activating the piezoelectric vibrator 1 configured in this manner, a predetermined drive voltage is applied to the external electrodes 38, 39 formed on the base substrate 2. Accordingly, an electric current can be flowed to the excitation electrode 15 including the first excitation electrode 13 and the second excitation electrode 14 of the piezoelectric vibration reed 4, so that the pair of vibrating arm portions 10, 11 can be vibrated at a predetermined frequency in the direction toward and apart from each other. Then, the vibration of the pair of vibrating arm portions 10, 11 can be used as a time instance source, a timing source of the control signal, a reference signal source, and so on.

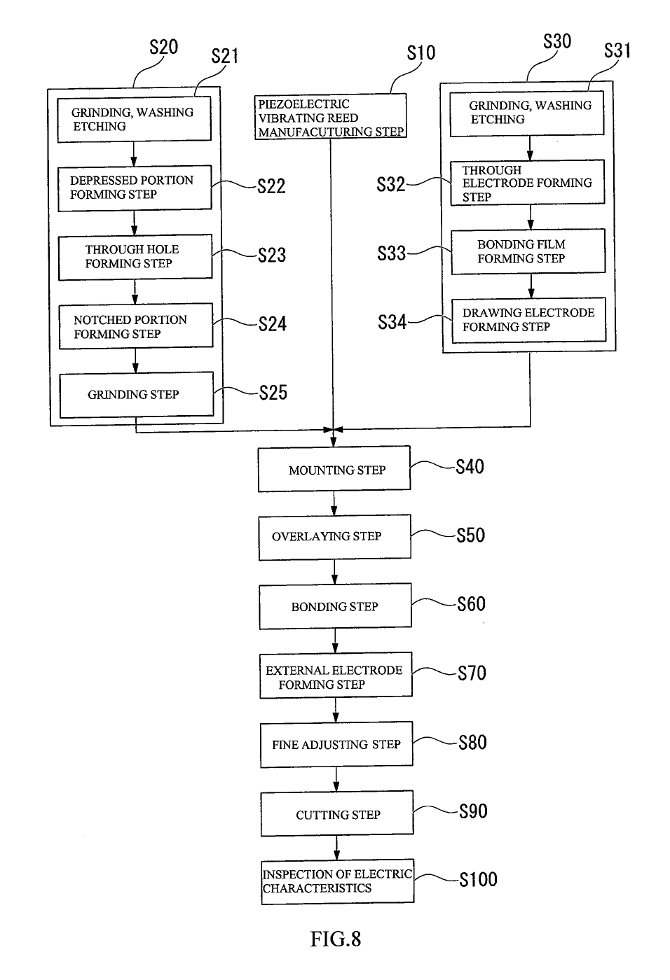

Subsequently, referring to a flowchart shown in FIG. 8, a manufacturing method for manufacturing a plurality of the above-described piezoelectric vibrators 1 using a base substrate wafer 40 and a lid substrate wafer 50 at once will be described below.

First of all, a piezoelectric vibration reed fabricating step is performed to fabricate the piezoelectric vibration reed 4 shown in FIG. 5 to FIG. 7 (S10). More specifically, Lambert row stone of crystal is sliced at a predetermined angle to obtain a wafer of a certain thickness at first. Subsequently, the wafer is wrapped and coarsely machined, then an affected-by-processing layer is removed by etching, and then mirror grinding process such as polishing is performed to obtain a wafer having a predetermined thickness. Subsequently, after having treated the wafer adequately such as washing, patterning of the outer shape of the piezoelectric vibration reed 4 is performed on the wafer and then formation and patterning of the metallic film are performed thereon with lithography technique, so that the excitation electrodes 15, the drawn electrodes 19, 20, the mount electrodes 16, 17, and the weight metal film 21 are formed. Accordingly, a plurality of the piezoelectric vibration reeds 4 can be fabricated.

Also, after having fabricated the piezoelectric vibration reed 4, the coarse adjustment of the resonance frequency is performed. This is achieved by irradiating the coarse adjustment film 21a of the weight metal film 21 with a laser beam to cause part of them to evaporate and changing the weight. Fine adjustment for adjusting the resonance frequency with higher degree of accuracy is performed after having mounted. This will be described later.

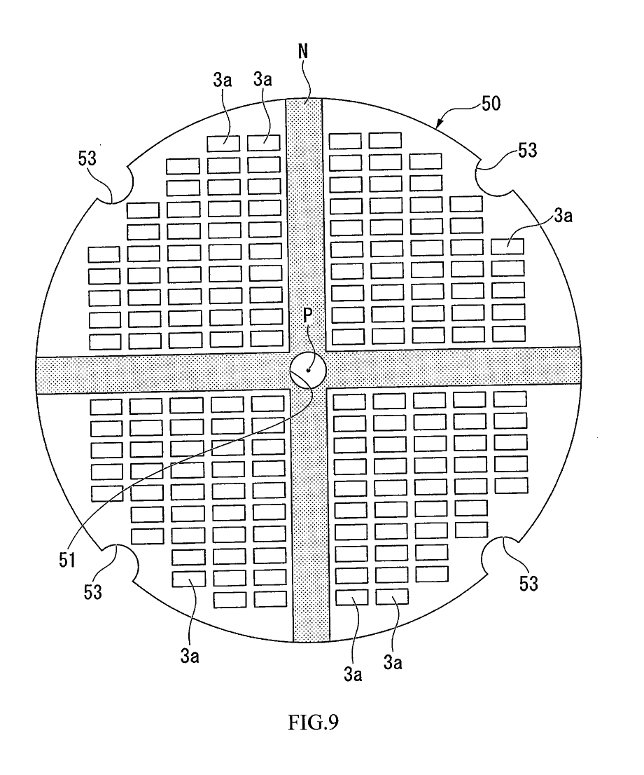

Subsequently, a first wafer fabricating step for fabricating the lid substrate wafer 50 which becomes the lid substrate 3 later to a state immediately before performing the anodic wafer bonding is performed (S20). First of all, after having been subjected to the grinding process the lid substrate wafer 50 formed of the soda-lime glass to a predetermined thickness and washed the same, the lid substrate wafer 50 of a disc shape having the affected-by-processing layer on the topmost surface thereof removed by etching or the like is formed as shown in FIG. 9 (S21). Subsequently, a depressed portion forming step for forming the plurality of depressed portions 3a for cavity in the direction of arrangement of rows by a method of etching process or the like on a bonding surface of the lid substrate wafer 50 is performed (S22). Since the depressed portions 3a ensure the rigidity of the lid substrate wafer 50, a non-cavity formed area N where the depressed portions 3a are not formed is provided into substantially a cross-shape including a center portion P of the lid substrate wafer 50.

A through hole 51 is formed in the non-cavity formed area N (S23). The through hole 51 is formed substantially simultaneously with the formation of the depressed portions 3a. In addition, substantially semicircular-shaped notched portions 53 are formed at four positions at substantially equidistantly in the circumference direction of the lid substrate wafer 50 (S24). The notched portions 53 are formed substantially simultaneously with the formation of the depressed portions 3a and the through hole 51.

When the depressed portions 3a, the through hole 51, and the notched portions 53 are formed, the surface where the depressed portions 3a are formed is ground to be ready for a bonding step (S60) (S25). At this time point, the first wafer manufacturing step is ended.

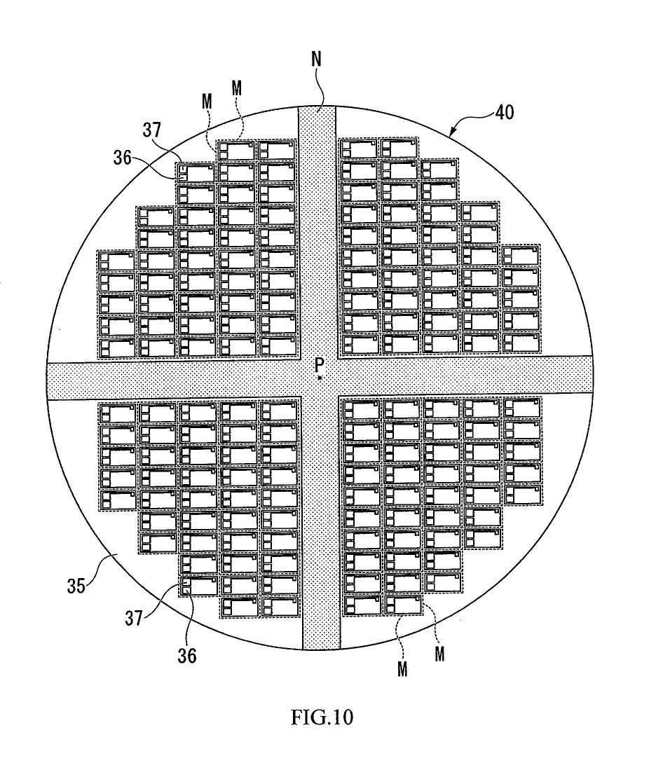

Subsequently, simultaneously with or a timing before or after the steps described above, a second wafer fabricating step for fabricating the base substrate wafer 40 which becomes the base substrate 2 later to a state immediately before performing the anodic wafer bonding is performed (S30). First of all, after having been subjected to the grinding process, the soda-lime glass to a predetermined thickness and washed the same, the base substrate wafer 40 of a disc shape having the affected-by-processing layer on the topmost surface thereof removed by etching or the like is formed (S31). Subsequently, a through electrode forming step for forming a plurality of pairs of through electrodes 32, 33 on the base substrate wafer 40 is performed (S32). The through electrodes 32, 33 are formed, for example, by forming the through holes 30, 31 on the base substrate wafer 40 at predetermined positions, filling the conductive material such as silver paste in the through holes 30, 31, and then baking the same. At this time, as shown in FIG. 10, in the same manner as the lid substrate wafer 50, the non-cavity formed area N where the through electrodes 32, 33 are not formed is provided into substantially a cross-shape including the center portion P of the base substrate wafer 40 for securing rigidity.

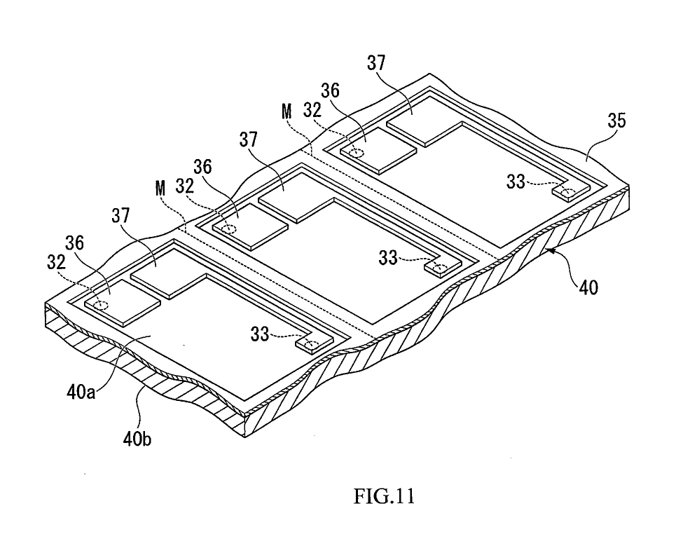

Subsequently, a bonding film forming step for patterning the conductive material and forming the bonding film 35 on an upper surface of the base substrate wafer 40 is performed (S33), and an drawing electrode forming step for forming a plurality of drawing electrodes 36, 37 electrically connected respectively to the pair of through electrodes 32, 33 is performed as shown in FIGS. 10, 11 (S34). Broken lines M shown in FIGS. 10, 11 indicate cutting lines to be cut in a cutting step performed later.

Specifically, the through electrodes 32, 33 are in substantially flush with the upper surface of the base substrate wafer 40 as described above. Therefore, the drawing electrodes 36, 37 patterned on the upper surface of the base substrate wafer 40 come into tight contact with the through electrodes 32, 33 without generating a gap therebetween. Accordingly, the conductivity between the one drawing electrode 36 and the one through electrode 32, and the conductivity between the other drawing electrode 37 and the other through electrode 33 can be secured. At this time point, the second wafer fabricating step is ended.

Incidentally, in FIG. 8, the order of the steps is illustrated as performing the drawing electrode forming step (S34) after the bonding film forming step (S33). However, conversely, the bonding film forming step (S33) may be performed after the drawing electrode forming step (S34) or the both steps may be performed simultaneously. In any step sequence, the same effects and advantages are achieved. Therefore, the step sequence can be changed adequately as needed.

Subsequently, a mounting step for bonding the fabricated plurality of piezoelectric vibration reeds 4 to an upper surface 40a (see FIG. 11) of the base substrate wafer 40 respectively via the drawing electrodes 36, 37 is performed (S40). First of all, the bumps B formed of gold or the like are formed respectively on the pair of drawing electrodes 36, 37. Then, the base members 12 of the piezoelectric vibration reeds 4 are placed on the bumps B, and then, the piezoelectric vibration reeds 4 are pressed against the bumps B while heating the bumps B to a predetermined temperature. Accordingly, the piezoelectric vibration reeds 4 are mechanically supported by the bumps B, while the mount electrodes 16, 17 and the drawing electrodes 36, 37 are electrically connected. Therefore, at this time point, the pairs of the excitation electrodes 15 of the piezoelectric vibration reeds 4 are brought into continuity with respect to the pairs of the through electrodes 32, 33.

In particular, since the piezoelectric vibration reeds 4, being bonded via the bumps, are supported in a state of floating from the upper surface 40a of the base substrate wafer 40.

After having mounted the piezoelectric vibration reeds 4, an overlaying step (S50) for overlaying the lid substrate wafer 50 on the base substrate wafer 40 is performed. Specifically, the both wafers 40, 50 are aligned at a proper position with reference to a reference mark or the like, not shown. Accordingly, a state in which the mounted piezoelectric vibration reeds 4 are stored in the cavities C surrounded by the depressed portions 3a formed on the lid substrate wafer 50 and the both wafers 40, 50 is achieved.

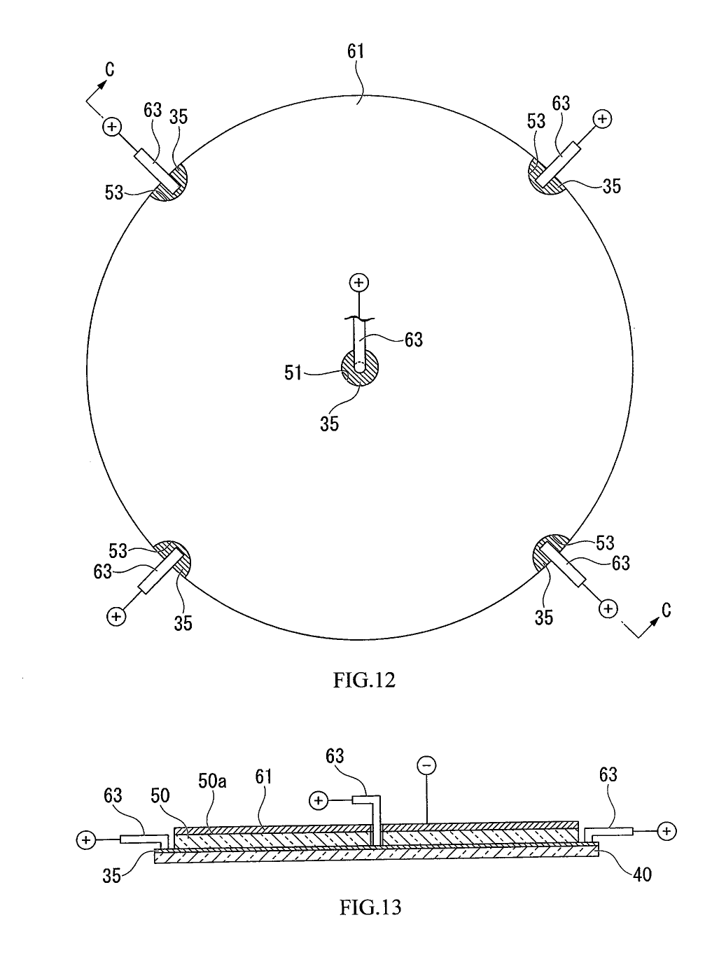

After having performed the overlaying step, the two overlaid wafers 40, 50 are put in an anodic wafer bonding apparatus, not shown, and a bonding step for applying a predetermined voltage in predetermined vacuum atmosphere and predetermined temperature atmosphere to bond the wafers 40, 50 by anodic wafer bonding is performed (S60). More specifically, as shown in FIG. 12, FIG. 13, the two overlaid wafers 40, 50 are placed in an anode apparatus. At this time, placement is made such that the base substrate wafer 40 comes to the lower side and the lid substrate wafer 50 comes to the upper side. Subsequently, an electrode panel 61 formed of the conductive material is placed on an upper surface 50a of the lid substrate wafer 50. The electrode panel 61 is a plate-shaped member formed into substantially the same shape in plan view as the lid substrate wafer 50. The electrode panel 61 functions as a minus terminal. In addition, electrodes 63 for applying a voltage are connected to the bonding film 35 exposed via the through hole 51 and the notched portions 53 of the lid substrate wafer 50 as plus terminals. In other words, the electrodes 63 are connected to the bonding film 35 at five points.

After having set as described above, a predetermined voltage is applied between the electrodes 63 connected to the bonding film 35 and the electrode panel 61. Then, an electrochemical reaction occurs in an interface between the bonding film 35 and the lid substrate wafer 50, and the both are tightly adhered to each other and bonded by anodic wafer bonding.

In this embodiment, since the voltage is applied in a state in which the electrodes 63 are connected to five points of the bonding film 35, the anodic wafer bonding starts substantially simultaneously from the five points in this manner, so that the anodic wafer bonding is performed in sequence. Also, by applying the voltage from the five points, a current value flowing at one point can be reduced to one-fifths, whereby the bonding film 35 can be prevented from being damaged by a high current.

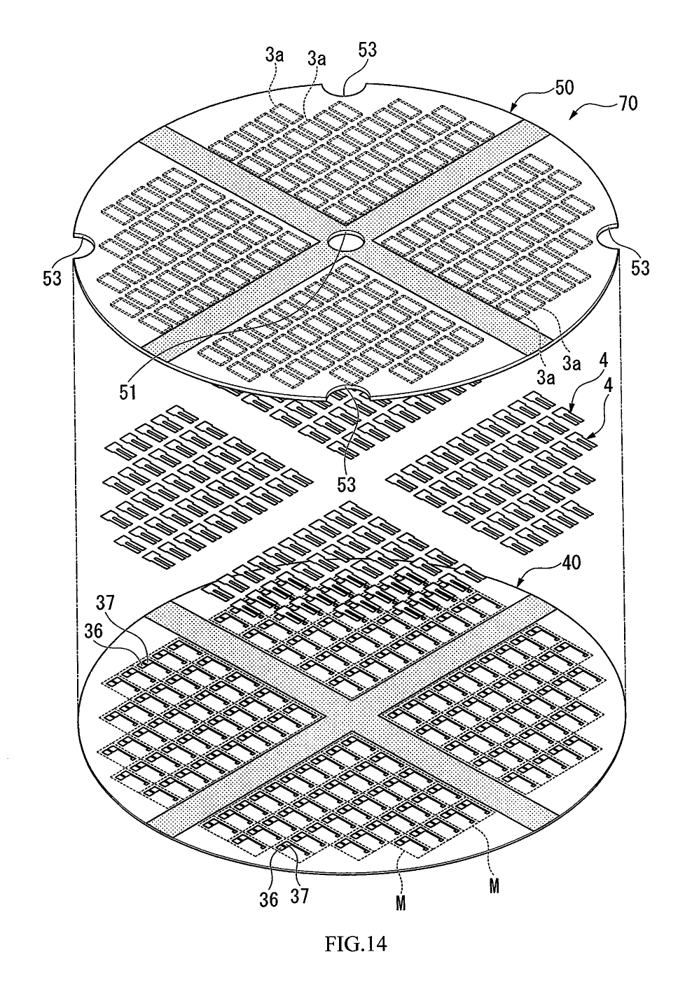

In this manner, by anodically bonding the two wafers 40, 50, the piezoelectric vibration reeds 4 can be sealed in the cavities C held in a vacuum state, and a wafer member 70 shown in FIG. 14 including the base substrate wafer 40 and the lid substrate wafer 50 bonded to each other can be obtained. In FIG. 14, for the sake of easy understanding of the drawing, a state in which the wafer member 70 is disassembled is illustrated, and illustration of the bonding film 35 is omitted from the base substrate wafer 40. The broken lines M shown in FIG. 14 indicate the cutting lines to be cut in the cutting step performed later.

Incidentally, when performing the anodic wafer bonding, the through holes 30, 31 formed on the base substrate wafer 40 are completely clogged up by the through electrodes 32, 33, so that the air-tightness in the cavities C does not impaired through the through holes 30, 31.

After having ended the above-described anodic wafer bonding, an external electrode forming step (S70) for patterning the conductive material on a lower surface 40b of the base substrate wafer 40 and forming a plurality of the pair of external electrodes 38, 39 connected electrically to the pair of through electrodes 32, 33 respectively is performed (S70). With this step, the piezoelectric vibration reeds 4 sealed in the cavities C can be operated using the external electrodes 38, 39.

In particular, when performing this process as well, in the same manner as when forming the drawing electrodes 36, 37, the through electrodes 32, 33 assume a state of being substantially flush with the lower surface 40b of the base substrate wafer 40, so that the patterned external electrodes 38, 39 come into tight contact with the through electrodes 32, 33 without generating the gap therebetween. Accordingly, conductivity between the external electrodes 38, 39 and the through electrodes 32, 33 can be ensured.

Subsequently, in the state of the wafer member 70, a fine-adjusting step for fine-adjusting the frequencies of the individual piezoelectric vibrators 1 sealed in the cavities C so as to be kept within a predetermined range is performed (S80). Specifically, the piezoelectric vibrating reeds 4 are vibrated by applying a voltage to the pair of external electrodes 38, 39 formed on the lower surface 40b of the base substrate wafer 40. Then, a laser beam is applied from the outside through the lid substrate wafer 50 while measuring the frequency, and causes the fine adjustment film 21b of the weight metal film 21 to evaporate. Accordingly, since the weights on the distal ends of the pair of vibrating arm portions 10, 11 are changed, the frequencies of the piezoelectric vibrating reeds 4 can be fine-adjusted so as to fall within a predetermined range of the nominal frequency.

After having ended the fine adjustment of the frequencies, the cutting step (S90) for cutting the bonded wafer member 70 into pieces along the cutting lines M shown in FIG. 14 is performed. Consequently, a plurality of the two-layer structure surface mount type piezoelectric vibrators 1 shown in FIG. 1 each having the piezoelectric vibration reed 4 sealed in the cavity C formed between the base substrate 2 and the lid substrate 3 which are anodically bonded to each other can be manufactured at once.

A step sequence such that the fine-adjusting step (S80) is performed after having performed the cutting step (S90) and cut into individual pieces of piezoelectric vibrators 1 is also applicable. However, by performing the fine-adjusting step (S80) precedently, the fine adjustment in a state of the wafer member 70 is achieved, so that a plurality of the piezoelectric vibrators 1 can be fine-adjusted efficiently. Accordingly, improvement of the throughput is achieved, which is preferable.

Subsequently, an inspection of the electric characteristics in the interior is performed (S100). In other words, a resonance frequency, a resonant resistance value, and drive level characteristics (an existing power dependency of the resonance frequency and the resonant resistance value) and the like are measured and checked. Insulative resistance characteristics are also checked. Then, finally, an appearance inspection of the piezoelectric vibrator 1 is performed to finally check dimensions, quality, and the like. Accordingly, manufacture of the piezoelectric vibrator 1 is ended.

According to this embodiment, by applying a voltage to the bonding film 35 from a plurality of points when performing the anodic wafer bonding for the base substrate wafer 40 and the lid substrate wafer 50, a current value flowing per point can be reduced. Therefore, the bonding film 35 can be prevented from being damaged by a heavy current, so that the anodic wafer bonding between the base substrate wafer 40 and the lid substrate wafer 50 is ensured. In other words, the piezoelectric vibrators 1 in which the base substrate 2 and the lid substrate 3 are anodically bonded therebetween with high reliability can be manufactured. In addition, by setting the number of points where the voltage is applied according to the size of the wafers to be anodically bonded, the piezoelectric vibrators 1 which are anodically bonded with high reliability irrespective of the size of the wafers can be manufactured. In other words, increase in diameter of the wafers is easily accommodated. In addition, since the bonding film 35 can be prevented from being damaged, the yield ratio can be improved.

Since the voltage is applied from a plurality of circumferentially equidistant points to the center portions P of the both wafers 40, 50 when performing the anodic wafer bonding, the voltage is applied to the center portion P of the both wafers 40, 50 in a well-balanced manner, the current value flowing through the bonding film 35 can be uniformized. Therefore, the anodic wafer bonding can be performed in substantially uniform conditions for the entire wafers, and then the quality of the plurality of piezoelectric vibrators 1 obtained by cutting the wafers into pieces can be uniformized.

Also, since the through hole 51 is formed at the center portion P of the lid substrate wafer 50 so as to apply the voltage to the bonding film 35 exposed through the through hole 51, the current value flowing through the bonding film 35 can be further uniformized. Therefore, the anodic wafer bonding can be performed in substantially uniform conditions for the entire wafers, and then the quality of the plurality of piezoelectric vibrators 1 obtained by cutting the wafers into pieces can be further uniformized.

In addition, with the configuration as described above, even though the both wafers 40, 50 are glass substrates, the bonding by the anodic wafer bonding is achieved.

### (Oscillator)

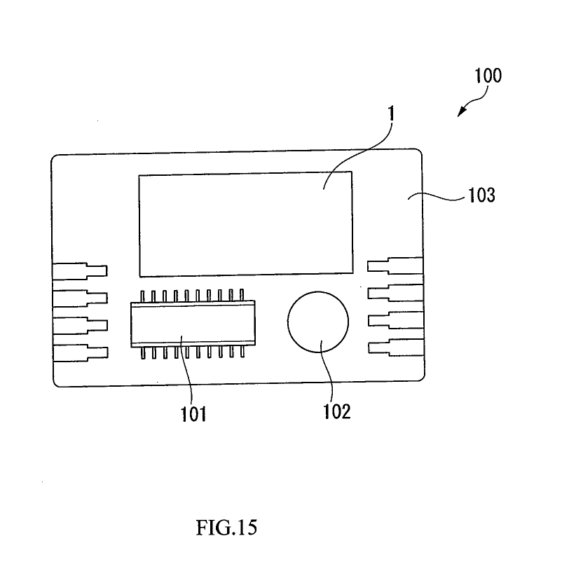

Subsequently, an embodiment of an oscillator according to the present invention will be described with reference to FIG. 15.

An oscillator 100 in this embodiment includes the piezoelectric vibrator 1 as an oscillation element electrically connected to an integrated circuit 101 as shown in FIG. 15. The oscillator 100 includes a substrate 103 on which an electronic component 102 such as a capacitor is mounted. The integrated circuit 101 as described above for the oscillator is mounted on the substrate 103, and the piezoelectric vibrator 1 is mounted in the vicinity of the integrated circuit 101. The electronic component 102, the integrated circuit 101, and the piezoelectric vibrator 1 are electrically connected to each other with a wring pattern, not shown. The respective components are molded by resin, not shown.

In the oscillator 100 configured as described above, when a voltage is applied to the piezoelectric vibrator 1, the piezoelectric vibration reed 4 in the piezoelectric vibrator 1 vibrates. This vibration is converted into an electric signal by piezoelectric characteristics of the piezoelectric oscillation reed 4 and is inputted to the integrated circuit 101 as the electric signal. The inputted electric signal is subjected to various sorts of processing by the integrated circuit 101, and is outputted as a frequency signal. Accordingly, the piezoelectric vibrator 1 functions as the oscillation element.

Also, by selectively setting the configuration of the integrated circuit 101, for example, an RTC (real time clock) module or the like according to the requirement, not only a function such as a single function oscillator for a clock, but also a function to control the date of operation or the time instant of the corresponding apparatus or an external apparatus or to provide the time instant or a calendar or the like of the same may be added.

As described above, with the piezoelectric vibrator 100 according to this embodiment, since the high-quality piezoelectric vibrator 1 in which the base substrate 2 and the lid substrate 3 are anodically bonded with high reliability, the air-tightness in the cavities C is reliably secured, the yield ratio is improved is provided, the continuity of the oscillator 100 by itself is also stably secured, and the reliability of the operation is enhanced and hence improvement in quality is achieved. In addition, stable and highly accurate frequency signals can be obtained over a long time.

### (Electronic Apparatus)

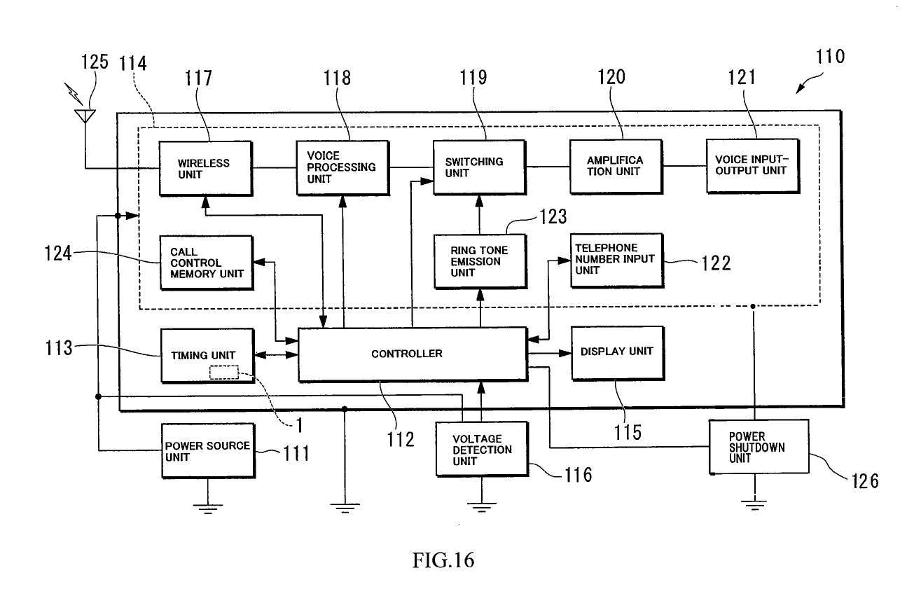

Subsequently, an embodiment of an electronic apparatus according to the present invention will be described with reference to FIG. 16. As the electronic apparatus, a portable digital assistant device 110 having the piezoelectric vibrator 1 described above will be exemplified for description.

First of all, the portable digital assistant device 110 in this embodiment is represented, for example, by a mobile phone set, and is development and improvement of a wrist watch in the related art. The appearance is similar to the wrist watch, and a liquid crystal display is arranged on a portion corresponding to a dial, so that the current time instance or the like can be displayed on a screen thereof. When using as a communication instrument, it is removed from the wrist, and communication as achieved by the mobile phone set in the related art can be performed with a speaker and a microphone built in an inner portion of a band. However, downsizing and weight reduction are achieved significantly in comparison with the mobile phone set in the related art.

Subsequently, a configuration of the portable digital assistant device 110 according to this embodiment will be described. The portable digital assistant device 110 includes the piezoelectric vibrator 1 and a power source unit 111 for supplying electric power as shown in FIG. 16. The power source unit 111 is composed, for example, of a lithium secondary battery. A control unit 112 configured to perform various controls, a clocking unit 113 configured to count the time instance or the like, a communication unit 114 configured to communicate with the outside, a display unit 115 configured to display various types of information, and a voltage detection unit 116 configured to detect the voltage of the respective functional portions are connected in parallel to the power source unit 111. Then, the power source unit 111 is configured to supply electric power to the respective functioning portions.

The control unit 112 controls respective functioning portions to perform operation control of an entire system such as sending and receiving of voice data, and measurement or display of the current time instance. Also, the control unit 112 includes a ROM in which a program is written in advance, a CPU configured to read and execute the program written in the ROM, and a RAM used as a work area of the CPU.

The clocking unit 113 includes an integrated circuit having an oscillating circuit, a register circuit, a counter circuit, and an interface circuit integrated therein, and the piezoelectric vibrator 1. When a voltage is applied to the piezoelectric vibrator 1, the piezoelectric vibration reed 4 vibrates, and this vibration is converted into an electric signal by piezoelectric characteristics of crystal and is inputted to the oscillating circuit as the electric signal. The output from the oscillating circuit is binarized, and is counted by the register circuit and the counter circuit. Then, sending and receiving of the signal with respect to the control unit 112 is performed via the interface circuit, and the current time instance, the current date, the calendar information, or the like are displayed on the display unit 115.

The communication unit 114 has the same function as the mobile phone set in the related art, and includes a wireless unit 117, a voice processing unit 118, a switch unit 119, an amplifying unit 120, a voice I/O unit 121, a phone number input unit 122, a ring tone generating unit 123, and a call control memory unit 124.

The wireless unit 117 sends and receives various data such as the voice data with respect to a base station via an antenna 125. The voice processing unit 118 codes and decodes a voice signal input from the wireless unit 117 or the amplifying unit 120. The amplifying unit 120 amplifies the signal inputted from the voice processing unit 118 or the voice I/O unit 121 to a predetermined level. The voice I/O unit 121 includes a speaker and a microphone, and reinforces ring tones or receiving voices, or collects voices.

Also, the ring tone generating unit 123 generates the ring tone according to the call from the base station. The switch unit 119 switches the amplifying unit 120 connected to the voice processing unit 118 to the ring tone generating unit 123 only at the time of the incoming call, so that the ring tone generated by the ring tone generating unit 123 is outputted to the voice I/O unit 121 via the amplifying unit 120.

The call control memory unit 124 stores the program relating to communication dialing and incoming ring tone control. Also, the phone number input unit 122 includes, for example, numeral keys from 0 to 9 and other keys, and a phone number of a call target is entered by pressing these numeral keys and the like.

The voltage detection unit 116 detects a voltage drop when the voltage applied to the respective functional portions such as the control unit 112 by the power source unit 111 falls below the predetermined value, and notifies it to the control unit 112. The predetermined voltage at this time is a value preset as a minimum voltage required for stably operating the communication unit 114 and, for example, is on the order of 3V. The control unit 112, upon reception of the notification about the voltage drop from the voltage detection unit 116, restricts the operations of the wireless unit 117, the voice processing unit 118, the switch unit 119, and the ring tone generating unit 123. In particular, the stop of the operation of the wireless unit 117 which consumes a large amount of power is essential. Furthermore, the fact that the communication unit 114 is disabled due to the short of the remaining amount of battery is displayed on the display unit 115.

In other words, the operation of the communication unit 114 may be restricted by the voltage detection unit 116 and the control unit 112, and this may be displayed on the display unit 115. This display may be a text message, but may be a cross mark on a telephone icon displayed on an upper portion of a display surface of the display unit 115 as a further visceral display.

By providing a power source blocking unit 126 which is capable of selectively block the power source of a portion relating to the function of the communication unit 114, the function of the communication unit 114 can be stopped further reliably.

As described above, with the portable digital assistant device 110 according to this embodiment, since the high-quality piezoelectric vibrator 1 in which the base substrate 2 and the lid substrate 3 are anodically bonded with high reliability, the air-tightness in the cavities C are reliably secured, the yield ratio is improved is provided, the continuity of the portable digital assistant device by itself is stably secured as well, and the reliability of the operation is enhanced and hence improvement in quality is achieved. In addition, a stable and highly accurate time information can be displayed over a long time.

### (Radio Clock)

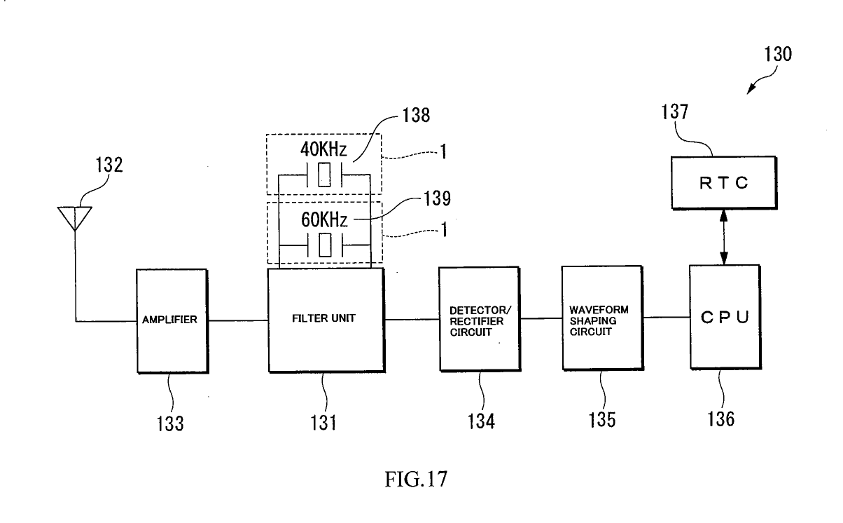

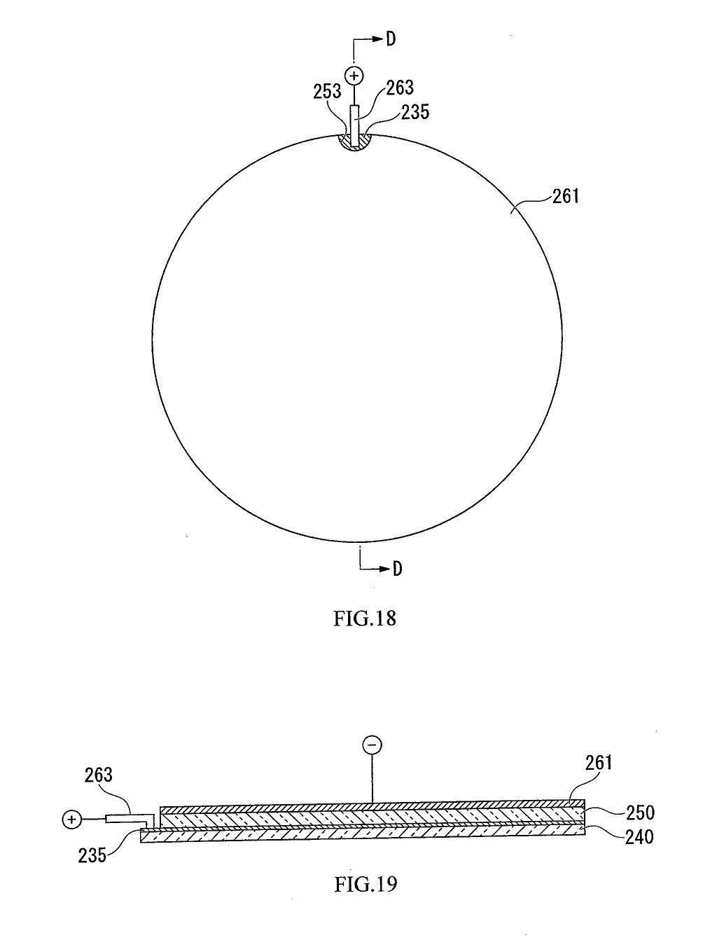

Subsequently, an embodiment of a radio clock according to the present invention will be described with reference to FIG. 17.

A radio clock 130 in this embodiment includes the piezoelectric vibrator 1 electrically connected to a filter unit 131 as shown in FIG. 17, and is a clock having functions to receive a standard radio wave including clock data, correct automatically the same to an accurate time instance, and display the same.

In Japan, transmitter points (transmitter stations) which transmit the standard radio wave in Fukushima-ken (40 kHz) and Saga-ken (60 kHz), and these stations transmit the standard radio waves respectively. Long radio waves such as 40 kHz or 60 kHz have both a feature to propagate on the ground surface and a feature to propagate while being reflected between the ionized layer and the ground surface, so that it has a large propagation range, and hence Japan is entirely covered by the above-described two transmitter stations.

A functional configuration of the radio clock 130 will be described in detail below.

An antenna 132 receives a long standard radio wave of 40 kHz or 60 kHz. The long reference radio wave is generated by AM modulating the time instance data referred to as a time code into a carrier wave of 40 kHz or 60 kHz. The received long reference radio wave is amplified by an amplifier 133 and filtered and synchronized by the filter unit 131 having the plurality of piezoelectric vibrators 1.

The piezoelectric vibrators 1 in this embodiment each include quartz vibrator units 138, 139 having a resonance frequency of 40 kHz and 60 kHz which is the same as the above-described carrier frequency.

Furthermore, the filtered signal having the predetermined frequency is detected and demodulated by a detection-rectification circuit 134.

Subsequently, the time code is acquired via a waveform shaping circuit 135, and is counted by a CPU 136. In the CPU 136, data such as the current year, the total day, the day of the week, the time instance is read. The read data is reflected on an RTC 137, and the accurate time instance data is displayed. Since the carrier wave is of 40 kHz or 60 kHz, the quartz vibrator units 138, 139 are preferably vibrators having the tuning fork type structure described above.

The description given above is about the example in Japan and the frequency of the long reference radio wave is different in other countries. For example, in Germany, a standard frequency of 77.5 KHz is used. Therefore, when integrating the radio clock 130 for overseas use into portable equipment, the piezoelectric vibrator 1 having a different frequency from Japan is further necessary.

As described above, with the radio clock 130 according to this embodiment, since the high-quality piezoelectric vibrator 1 in which the base substrate 2 and the lid substrate 3 are anodically bonded with high reliability, the air-tightness in the cavities C are reliably secured, and the yield ratio is improved is provided, the continuity of the radio clock by itself is stably secured, and the reliability of the operation is enhanced and hence improvement in quality is achieved. In addition, stable and highly accurate time count is achieved over a long time.

The present invention is not limited to the embodiments shown above, and various modifications may be made without departing the scope of the present invention.

For example, although the grooved piezoelectric vibration reed 4 having the groove portions 18 on both surfaces of the vibrating arm portions 10, 11 has been described as an example of the piezoelectric vibration reed 4 in the above-described embodiment, the piezoelectric vibration reed of a type having no groove portion 18 is also applicable. However, since field efficiency between the pair of excitation electrodes 15 when a predetermined voltage is applied to the pair of excitation electrodes 15 by forming the groove portion 18, vibration characteristics can be improved while further reducing the vibration loss. In other words, the CI value (Crystal Impedance) can further be reduced, and further improvement in performance of the piezoelectric vibration reeds 4 is achieved. From this point, it is more preferable to form the groove portions 18.

In the embodiment described above, although the piezoelectric vibration reed 4 of the tuning fork type is exemplified, the invention is not limited to the tuning fork type. For example, a thickness-shear vibration reed may be employed.

In the embodiment described above, although the piezoelectric vibration reed 4 is bonded via the bumps, the invention is not limited to the bump bonding. For example, the piezoelectric vibration reed 4 may be bonded with conductive adhesive agent. However, by performing the bump bonding, the piezoelectric vibration reed 4 can be raised from the upper surface of the base substrate 2, so that the minimum vibration gap required for vibrations can be naturally secured. Therefore, the bonding via the bumps is preferred.

In the embodiment described above, although the case where the notches 53 at four points and the through hole 51 at one point are formed on the lid substrate wafer 50, and a voltage is applied from the five points for achieving the anodic wafer bonding has been described, the number of points to be applied with the voltage may be other numbers. Also, a configuration in which the bonding film 35 is formed on the lid substrate wafer 50, and the notches 53 and the through hole 51 are formed on the base substrate wafer 40 is also applicable.

Furthermore, although the method of manufacturing the piezoelectric vibrators has been described in the embodiment described above, since it can be applied to a case of performing the anodic wafer bonding between a pair of the wafers, it can be employed not only in the piezoelectric vibrator, but also in other package products.

A method of manufacturing piezoelectric vibrators according to the present invention can be applied to the method of manufacturing the piezoelectric vibrators of a surface mount type (SMD) in which a piezoelectric vibration reed is sealed in a cavity formed between bonded two substrates.

What is claimed is:

1. An anodic wafer bonding method for bonding a first substrate formed of an insulating material or a dielectric material and a second substrate which can be anodically bonded by applying a voltage to a bonding film formed of a conductive material formed between the substrates in a state in which the first substrate and the second substrate are laminated, comprising:
applying the voltage to the bonding film from a plurality of points at the time of anodic wafer bonding.

2. The anodic wafer bonding method according to claim 1, characterized in that
the voltage is applied to a center portion of the first substrate or the second substrate from a plurality of circumferentially equidistant points.

3. The anodic wafer bonding method according to claim 2, characterized in that
a through hole is formed at the center portion on any one of the first substrate and the second substrate, and the voltage is applied to the bonding film formed at the position corresponding to the center portion.

4. The anodic wafer bonding method according to claim 1, characterized in that
the first substrate and the second substrate are glass substrates.

5. A method of manufacturing packages comprising:
forming depressed-shaped cavities on at least one of the first substrate or the second substrate; and
bonding and integrating the first substrate and the second substrate by the anodic wafer bonding method according to claim 1, and then dividing the integrated substrates into individual pieces and forming a plurality of packages.

6. A method of manufacturing piezoelectric vibrators comprising:
forming depressed cavities on at least one of the first substrate and the second substrate, and then mounting piezoelectric vibration reeds in the cavities;
bonding and integrating the first substrate and the second substrate by the anodic wafer bonding method according to claim 1, and then dividing the integrated substrates into individual pieces and forming a plurality of piezoelectric vibrators.

7. An oscillator characterized in that the piezoelectric vibrator manufactured by the manufacturing method according to claim 6 is electrically connected to an integrated circuit as an oscillation element.

8. An electronic apparatus characterized in that the piezoelectric vibrator manufactured by the manufacturing method according to claim 6 is electrically connected to a clocking unit.

9. A radio clock characterized in that the piezoelectric vibrator manufactured by the manufacturing method according to claim 6 is electrically connected to a filter unit.
